(19) United States
(12) Patent Application Publication
(10) Pub. No.: US 2008/0012571 A1
(43) Pub. Date: Jan. 17, 2008

(54) Measuring Device And Measuring Procedure For Determining Battery Cell Voltages

(76) Inventors: Martin Ehrmann, Nurnberg (DE); Wolfgang Schmidt, Furth (DE)

Correspondence Address: CONTINENTAL TEVES, INC., ONE CONTINENTAL DRIVE, AUBURN HILLLS, MI, 48326-1581, US

(21) Appl. No.: 11/568,528

(22) PCT Filed: Mar. 26, 2005
(86) PCT No.: PCT/DE05/00545

§ 371 Date: Oct. 31, 2006

(30) Foreign Application Priority Data
May 4, 2004 (DE) 10 2004 022 220.7
Sep. 28, 2004 (DE) 10 2004 046 956.3

(51) Int. Cl. G01R 31/36

(52) U.S. Cl. 324/434

(57) ABSTRACT

With a measuring device (1) for determining a voltage of at least one battery cell (14) in a battery (15), it is provided in order to achieve a precise, highly accurate measurement, that a voltage which is applied to an integration circuit (2) is integrated up and in a first and a second comparator circuit (4, 5) is compared with a first and a second comparator threshold value. The time span between the emission of a first and a second switching value is measured using a measuring and evaluation unit (6). In addition, a reference voltage source (3) is provided in order to specify a reference voltage. Due to the fact that in two integration procedures in sequence, a voltage which comprises the reference voltage and a voltage which comprises the voltage of a battery cell (14) to be determined is integrated up, the unknown voltage of the battery cell (14) can be precisely determined by comparing the two integration procedures. Additionally, a procedure for determining the voltage of a battery cell (14) using a measuring device (1) according to the invention is given.

The invention relates to a measuring device for determining a voltage of at least one battery cell in a battery. The invention furthermore relates to a procedure for determining a voltage with a measuring device according to the invention.

Batteries frequently consist of a plurality of battery cells which are connected in series. In order to operate the batteries in motor vehicles, for example in a hybrid motor vehicle or in an electric motor vehicle, a precise measurement of the voltage of each battery cell is required in order to avoid the battery cells from becoming under- or overcharged.

The capacity of a battery depends on the precision of the voltage measurement, since the tolerance of the measurement on the over- and undercharging threshold must be maintained, in order to prevent damage occurring to the battery cells. In addition, the cells of specific types of battery, such as the cells of batteries based on lithium ions, are actively discharged onto the voltage level (or close to the voltage level) of the battery cell with the lowest voltage (compensation of the different self-discharging currents). For these reasons, a precise measurement of the voltages of the battery cells in a battery is required.

In US 20020180447, a measuring device is disclosed with which each battery cell is provided with a differential amplifier in order to measure the voltages. The disadvantage with this known measuring device is that each differential amplifier must fulfill high standards with regard to the common mode voltage suppression in order to achieve a precise measurement, as a result of which the measuring device is expensive. Furthermore, the measuring device causes a systematic measuring error due to the fact that the constant calibration voltage and the variable cell voltages are generally not identical.

In U.S. Pat. No. 5,914,606, a measuring device is described with which the voltage of each battery cell is divided using a voltage separator. The outputs of the voltage separator are guided onto multiplexers, via which two of the voltage separator outputs are selected. The differential voltage on the two multiplexer outputs is amplified, and thus switched to the voltages of the battery cells. The disadvantage with this measuring device is that the resistance influences of the voltage separators must be extremely precise. Due to the unavoidable drift in temperature and age of the resistances, the measuring device is thus not suitable for taking precise measurements in a vehicle.

A measuring device is known from JP 2003240806, with which a switchable network is used to switch a capacitor in sequence to a battery cell and a differential amplifier with an A/D converter. The disadvantage with this measuring device is that high-precision and thus, expensive construction elements, in particular a high-precision A/D converter, are required.

Against this background, the object of the invention is to further develop a measuring device of the type named in the introduction in such a manner that the voltages of the individual battery cells in the battery can be determined in a highly precise and cost-efficient way.

This object is attained by means of a measuring device with the features described in patent claim 1.

The core idea of the invention is that the determination of the voltage of a battery cell is based on the measurement of two time spans, which are set in relationship to each other. For this purpose, the integrator circuit is first initialised, i.e., it is brought to a value below the two comparator threshold values using the up integration procedure described below. Then, a voltage which comprises the reference voltage is applied to the circuit inputs of the integrator circuit, and the voltage is integrated up until the circuit output of the integrator circuit has reached the first and second comparator threshold value. The first and second comparator circuits emit a first and second switching value on the first and second comparator output when their comparator threshold values are reached. The time between the emission of the first switching value and the emission of the second switching value is measured by the measuring and evaluation unit, and defines the first time span. Furthermore, a voltage which comprises the voltage of a battery cell to be determined is applied to the circuit inputs of the integrator circuit, and is integrated up until the circuit output of the integrator circuit has reached the first and second comparator threshold value. The time between the emission of the first and second threshold value is in turn measured by the measuring and evaluation unit, and forms the second time span. The two measurements are set in relation to each other, as a result of which the voltage of the battery cell to be determined can be calculated.

Since the two measurements are taken within a short period of time and are set in relation to each other, the temperature and ageing influences in the measuring device are almost fully eliminated. No external recalibration of the measuring device due to temperature and ageing influences is required. In addition, systematic measuring errors, such as measuring errors due to the influence of the common mode voltage, can be mathematically eliminated, which enables high-precision measurement. Additionally, with the exception of the reference voltage source, no precision components such as a precision A/D converter, are required, which enables the measuring device to be realised in a cost-efficient manner. Furthermore, the integrator circuit is robust with regard to electromagnetic interferences.

A further embodiment according to claim 2 enables a high-precision, cost-effective realisation of the integrator circuit and the comparator circuits. In particular, the use of high-resolution A/D converters and a high-resolution measuring and evaluation unit is not required.

An embodiment according to claim 3 or 4 enables an analogue realisation of the integrator circuit with a capacitor and an operation amplifier in such a manner that the integrator circuit can be used for both negative and positive common mode voltages when integrating a voltage of a cell. Due to the fact that the circuit output of the integrator circuit is the voltage which is released via the capacitor and simultaneously, the common mode control of the operation amplifier, the integrator circuit runs through the same output voltage range during each integration procedure, and the operation amplifier therefore also runs through the same common mode input voltage range, regardless of the common mode voltage which is currently applied during the integration procedure of the voltage of the battery cell to be determined.

An embodiment according to claim 5 leads to a high level of measuring precision of the first and second time span. The further apart the comparator threshold values, the longer the integration procedure lasts until the second switching value is reached, as a result of which the resolution of the digital measuring and evaluation unit causes a lower measuring error relative to the time spans measured.

A further embodiment according to claim 6 leads to a defined reference potential of the measuring device relative to the battery.

An embodiment according to claim 7 enables a symmetrical arrangement of the earth potential relative to the battery cells, as a result of which the required common mode input voltage range of the integrator circuit can be reduced.

A further embodiment according to claim 8 enables the use of the measuring device in order to determine the voltages of several battery cells which are connected in series.

A further object of the invention is to provide a measuring procedure for determining a voltage of at least one battery cell in a battery using a measuring device according to the invention.

This object is attained according to the invention by means of a measuring procedure with the features described in patent claim 9. The advantages of the measuring procedure according to the invention correspond to those described above in relation to the measuring device according to the invention.

A further embodiment according to claim 10 enables a precise measurement of the first and second time span, since integration direction-dependent measuring errors do not enter into the determination of the voltage of the battery cell.

The embodiment according to claim 11 leads to the elimination of temperature and ageing influences, since due to the brief time difference, it can be assumed that the temperature and ageing conditions are unchanged.

Further features, advantages and details of the invention are included in the following description, in which a preferred exemplary embodiment of the invention is explained in further detail with reference to the appended drawings, in which:

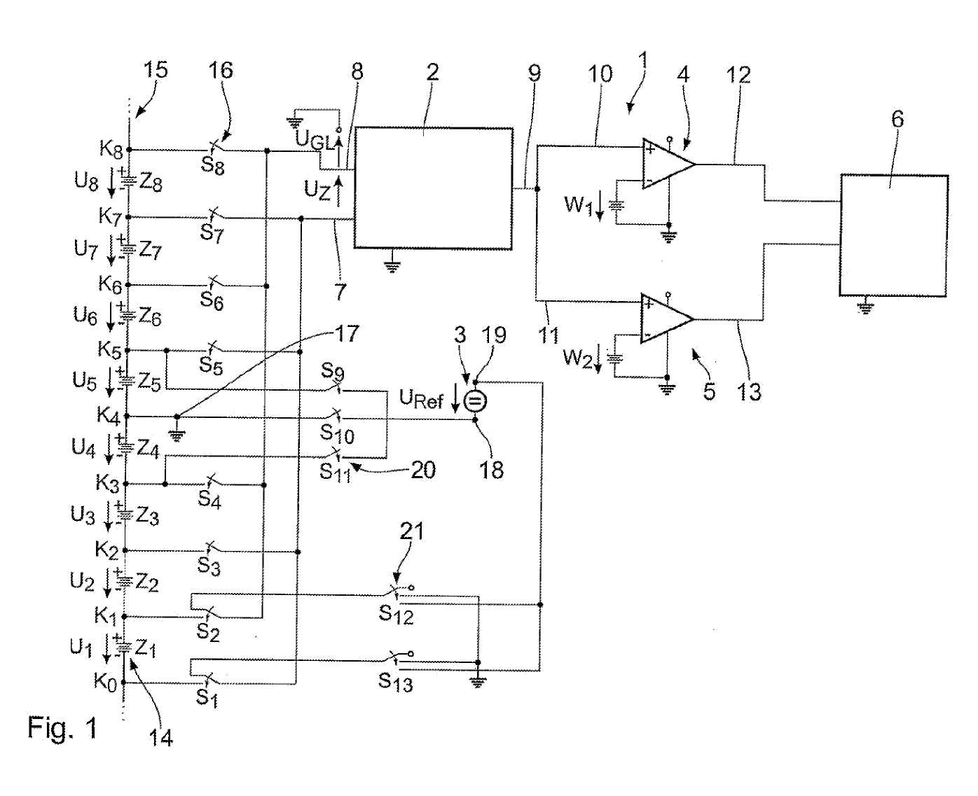

FIG. 1 shows a schematic circuit structure of a measuring device, and

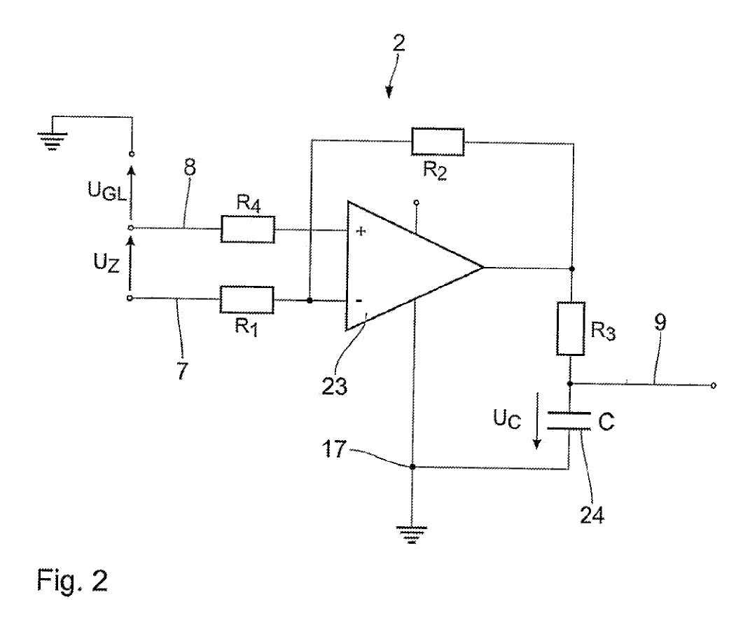

FIG. 2 shows an analogue integrator circuit according to FIG. 1

An overall measuring device, referred to as 1, comprises an integrator circuit 2, a reference voltage source 3, a first comparator circuit 4, a second comparator circuit 5 and a measuring and evaluation unit 6. The integrator circuit 2 is an analogue circuit, and comprises a first circuit input 7 and a second circuit input 8 for applying a voltage. In order to emit an integrated value, a circuit output 9 of the integrator circuit 2 is provided. The integrated value represents a voltage which characterises the integral via the voltage applied to the circuit inputs 7, 8.

The circuit output 9 of the integrator circuit 2 is connected with a first comparator input 10 of the first comparator circuit 4. The circuit output 9 is furthermore connected with a second comparator input 11 of the second comparator circuit 5. The comparator circuits 4, 5 are also analogue circuits. In order to compare the integrated value on the circuit output 9 with the first comparator threshold value, the first comparator circuit 4 comprises a first comparator output 12, on which when the first comparator threshold value is reached, a first switching value is emitted. In accordance with the first comparator circuit 4, the second comparator circuit 5 comprises a second comparator output 13, on which when the second comparator threshold value is reached, a second switching value is emitted. The two comparator circuits 4, 5 comprise comparator threshold values which deviate from each other, so that the emission of the first and the second switching value occurs at different times.

In order to measure the time span between the emission of the first switching value and the emission of the second switching value, the measuring and evaluation unit 6 is provided. The first and second comparator output 12, 13 are connected to the measuring and evaluation unit 6. The measuring and evaluation unit 6 is digital, and contains a facility which makes it possible to measure the time span between the switching events on the comparator outputs 12 and 13.

The measuring device 1 is provided for measuring the voltage of eight battery cells 14 in a battery 15. In principle, the number of battery cells 14 can be selected as required depending on the measuring device 1. In practise, however, it has shown to be effective to provide the measuring device 1 for eight battery cells 14, since a modular measuring structure is cost-effective and enables the voltage of all battery cells 14 to be determined within 50 ms.

The battery cells 14 will now be referred to individually as Z₁ to Z₈. Each battery cell Z₁ to Z₈ comprises a corresponding voltage U₁ to U₈ which is to be determined. The voltages U₁ to U₈ can in each case be recorded on two nodes, and applied to the circuit inputs 7, 8 of the integrator circuit 2. The nodes, which lie between the battery cells Z₁ to Z₈, are referred to individually as K₀ to K₈. The voltage of a battery cell 14 is 5 V. In order to achieve a good degree of effectiveness of the battery 15, a measurement of the cell voltage with a precision of 0.2% is required, which with a 5 V voltage on a battery cell 14 corresponds to a measuring precision of +/−10 mV.

In order to apply the voltages of the battery cells 14 to the circuit inputs 7, 8 of the integrator circuit 2, eight battery cell switches 16 are provided. The battery cell switches 16 are referred to individually as S₁ to S₈. With the switch S₁, the node K₀, with the switch S₃, the node K₂, with the switch S₅, the node K₅ and with the switch S₇, the node K₇ can be connected to the first circuit input 7 of the integrator circuit 2. By contrast, with the switch S₂, the node K₁, with the switch S₄, the node K₃, with the switch S₆, the node K₆ and with the switch S₈, the node K₈ can be connected to the second circuit input 8 of the integrator circuit 2. The battery cell switches S₁ to S₈ can take the “open” and “closed” positions, whereby in the “closed” position, they create the connection to the first or second circuit input 7, 8.

The measuring device 1 comprises an earth potential 17, which acts as a reference potential. The earth potential 17 is connected with the node K₄, so that the potential of the node K₄ is identical to the earth potential 17.

The reference voltage source 3 comprises a first voltage source connection 18 and a second voltage source connection 19. The first voltage source connection 18 can be connected via three voltage source switches 20 either with the node K₃, the node K₄ or the node K₅. The voltage source switches 20 are referred to individually as S_{9 to S}₁₁. Using the voltage source switch S₉, the first voltage source connection 18 can be connected with the node K₅, using the voltage source switch S₁₀ with the node K₄ and using the voltage source switch S₁₁ with the node K₃. The switches S_{9 to S}₁₁ can take an “open” and “closed” position.

The battery cell switches S₁ and S₂ are each connected when in their “open” position with a selector switch 21. The selector switches 21 are referred to individually as S₁₂ and S₁₃. The selector switch S₁₂ is connected with the battery cell switch S₂ and the selector switch S₁₃ is connected with the battery cell switch S₁. The selector switches S₂₁ can each take three positions. The first position is “open”, the second position is “earth” and the third position is “reference voltage”. In the second position, “earth”, the selector switches 21 are connected with the earth potential 17. By contrast, the selector switches in the third position, “reference voltage”, are connected to the second voltage source connection 19 of the reference voltage source 3. The reference voltage source 3 comprises a reference voltage between the first and second voltage source connection 18, 19, which is referred to below as U_{Ref}. The reference voltage U_{Ref} is known with a precision of 0.1%.

Between the first circuit input 7 and the second circuit input 8 of the integrator circuit 2, a voltage U_{Z} is defined, which represents the voltage to be determined. The voltage U_{Z} can be selected, when the position of the battery cell switch 16 is selected accordingly, as being equal to the individual voltages of the battery cells 14. Furthermore, a common mode voltage U_{GL} is defined, which characterises the potential difference between the second circuit input 8 and the earth potential 17.

The comparator circuits 4, 5 are analogue circuits, and in each case comprise one comparator operation amplifier 22 with one P-input and one N-input. The P-inputs of the comparator operation amplifiers 22 represent the first comparator input 10 or the second comparator input 11. The N-inputs of the comparator operation amplifiers are in each case connected with the earth potential 17, whereby between the N-inputs and the earth potential 17, the first comparator threshold value and the second comparator threshold value is released in the form of a voltage. The first comparator threshold value is referred to below as W₁, and the second comparator threshold value is referred to as W₂.

The voltages of the battery cells 14 to be determined total approximately 5 V. In order to measure the time span between the point when the first comparator threshold W₁ is reached and when the second comparator threshold W₂ is reached, a first switching value is emitted by the first comparator circuit 4 and a second switching value is emitted by the second comparator circuit 5. The time span is measured by the digital measuring and evaluation unit 6, which generates a quantisation error. The measuring error of the measuring and evaluation unit 6 is in percentage terms lower, the greater the time span between the emission of the first and second switching value. For this reason, it is advantageous to select the comparator threshold values W₁ and W₂ as far away as possible from each other. The first comparator threshold value W₁ thus equals 0.5 V and the second comparator threshold value W₂ equals 4.5 V. With the corresponding layout of the integrator circuit 2, a time span can therefore be measured which is greater than 1 ms, as a result of which the relative measuring error of the time span totals 0.05% maximum. The measuring error depends on the digital resolution of the measuring and evaluation unit 6, and can be set to a maximum value via a corresponding layout of the circuits 2, 4, 5 via the size of the time span to be measured.

FIG. 2 shows the precise structure of the integrator circuit 2. The integrator circuit 2 comprises an integrator operation amplifier 23, the N-input of which is connected via an ohmic resistance R₁ to the first circuit input 7 and the P-input of which is connected via an ohmic resistance R to the second circuit input 8. The output of the integrator operation amplifier 23 is reverse-coupled via an ohmic resistance R₂ to the N-input. The output of the integrator operation amplifier 23 is furthermore connected via an ohmic resistance R₃ and the capacitor 24 with the capacity C to the earth potential 17. Via the capacitor 24, the voltage U_{C} is released which is captured as the switching output 9. The integrator circuit 2 comprises the following differential equation when an ideal integrator operation amplifier 23 is assumed:

$$\begin{matrix}\frac{ⅆ {U}_{C}}{ⅆ t} = \frac{- {R}_{2}}{{R}_{1} \cdot {R}_{3} \cdot C} \cdot {U}_{Z} + \frac{1}{C} \cdot ( \frac{{R}_{2}}{{R}_{1} \cdot {R}_{3}} - \frac{1}{{R}_{4}} ) \cdot {U}_{C} + \\ \frac{1}{C} \cdot ( \frac{1}{{R}_{4}} - \frac{{R}_{2}}{{R}_{1} \cdot {R}_{3}} ) \cdot {U}_{GL}\end{matrix}$$

The time change in the capacitor voltage U_{C} is therefore dependent on the voltage which is applied and which is to be determined U_{Z}, on the current capacitor voltage U_{C}, on the common mode voltage U_{GL} and on the values of the ohmic resistances R₁ to R₄ and the capacity C of the capacitor 24. The values of the resistances R₁ to R₄ and the capacity C of the capacitor 24 depend on the temperature and the age. For integration with a time duration Δt, it can be assumed, however, that the values of the ohmic resistances R₁ to R₄ and the capacity C of the capacitor 24 are constant. Equally, the applied voltage U_{Z} and the common mode voltage U_{GL} can be assumed as being constant for the time At of the integration. The integration of the above equation thus gives:
ΔU_{C}=C₁·U_{Z}·Δt+C₂·Δt+C₃·U_{GL}·Δt

The constants C₁, C₂ and C₃ contain the values of the ohmic resistances R₁ to R₄, the capacity C of the capacitor 24 and the initial voltage U_{C0} of the capacitor 24 at the start of integration. Below, Δt refers to the time span between the output of the first switching value and the second switching value. ΔU_{C} refers in this case to the voltage difference between the second comparator threshold value and the first comparator threshold value W₂−W₁.

The values of the ohmic resistances R₁ to R₄ are selected in such a manner that the influence of the common mode voltage U_{GL} ideally becomes zero. This means that R₁=R₄, and R₂=R₃ is selected. The absolute value of the resistances R₁ and R₄ is furthermore selected in such a manner that the influence of the voltage release on the battery cell switches can be neglected. R₁ and R₄ comprise a value of 56.2 kOhm. The values of the resistances R₂ and R₃ and the capacity C of the capacitor 24 are selected in such a manner that the voltage of the battery cells 14 of 5 V is integrated in over 1 ms to a differential voltage of W₂−W₁=4 V, and the control limits of the integrator circuit 2 and the maximum power load are not exceeded. The values of the ohmic resistances R₂ and R₃ total 1 kOhm and the capacity C of the capacitor 24 totals 22 nF.

In the following, the principle for determining the voltages of the battery cells 14 and the functionality of the measuring device 1 will be explained. The comparator threshold values W₁ and W₂ of the comparator circuits 4, 5 are known only with a precision of several percent. Due to the fact that the measuring precision of the measuring device 1 must total at least 0.2%, it is absolutely necessary to eliminate the voltage difference ΔU_{C}. For this reason, two integration procedures are conducted, in which ΔU_{C} is assumed to be unknown, but constant. The measured time spans of the first and second integration procedure are referred to as Δt₁ and Δt₂. No temperature and ageing influences of the measuring device 1 are included in the measurement of the first and second time span when the two integration procedures are conducted in sequence within a sufficiently brief time period. Ideally, a time difference of maximum 2 ms lies between the end of the first integration procedure and the start of the second integration procedure. In practise, a time difference of 1.25 ms has been shown to be possible and advantageous. The integrator circuit 2 is reset prior to each integration procedure, i.e. when integrated up to a voltage which is lower than the two comparator threshold values W₁ and W₂ and when integrated down to a voltage which is greater than the two comparator threshold values W₁ and W₂. If the two measurements are set in relationship to each other, the following equation results:

$$1 = \frac{{C}_{1} \cdot {U}_{Z 1} \cdot Δ {t}_{1} + {C}_{2} \cdot Δ {t}_{1} + {C}_{3} \cdot {U}_{GL 1} \cdot Δ {t}_{1}}{{C}_{1} \cdot {U}_{Z 2} \cdot Δ {t}_{2} + {C}_{2} \cdot Δ {t}_{2} + {C}_{3} \cdot {U}_{GL 2} \cdot Δ {t}_{2}}$$

If the above equation is divided by C₁ and Δt_{V}=Δt₁/Δt₂ is inserted, the following results:
U_{Z2}=U_{Z1}·Δt_{V}·C₂₁·(1−Δt_{V})−C₃₁·(U_{GL2}−Δt_{V}·U_{GL1})
whereby for C₂₁=C₂/C₁ and C₃₁=C₃/C₁ applies. This equation is referred to below as the basic equation. The basic equation is used to determine the voltage U_{Z2} which represents the voltage of the battery cells 14 to be determined. The ratio of the time spans Δtᵥ is known from the measurements. Equally, the common mode voltage U_{GL1} of the first measurement and the common mode voltage U_{GL2} of the second measurement is known, as will be shown. The constants C₂₁ and C₃₁ are however dependent on the direction of integration, so that in order to achieve a high level of precision, the direction of integration of the first and second integration procedure must be identical. The voltage U_{Z1} of the first measurement is known, since it represents either the reference voltage U_{Ref} or a voltage which contains the reference voltage U_{Ref} and already determined voltages from battery cells 14. Through the formation of the quotients of the equations of two integration procedures, temperature and ageing influences of the measuring device 1 and other imprecisions of the measuring device 1 are not included in the determination of the voltages of the battery cells 14. In this way, a precision of at least 0.2% can be achieved when determining the voltages of the battery cells.

In the following, the determination of the voltages U₁ to U₈ of the battery cells 14 is described. For this purpose, all voltages are shown as positive in the direction of the arrow. For differentiation purposes, the constants C₂₁ and C₃₁ are referred to with an integration down (U_{Z}>0) as C_{21D} and C_{31D}, and with an integration up (U_{Z}<0) as C_{21U} and C_{31U}.

Initially, the constants C_{21D} and C_{31D} and the voltage U₄ must be determined. For each unknown parameter, two integration procedures must be conducted, and the corresponding time spans must be measured. Since C_{21D} and C_{31D} are initially unknown, two reference integration pairs must thus first be measured, each with a first and a second integration procedure.

The integration procedures of the first integration pair are referred to below as 1a and 1b. For the integration path 1a, the following switch settings are made: S₁=“open”, S₂=“open”, S₁₀=“closed”, S₁₂=“earth”, S₁₃=“U_{Ref}”. In this way, the following applies to the integration procedure 1a: U_{Z1}=U_{Ref} and U_{GL1}=0V. All other switches are “open”. For the second integration procedure 1b, the following switch settings are made: S₁=“open”, S₄=“closed”, S₁₀=“closed”, S₁₃=“U_{Ref}”. All other switches are “open”. In this way, the following applies to the second integration procedure 1b: U_{Z2}=U₄+U_{Ref} and U_{GL2}=−U₄. When both integration procedures are conducted, two time spans are measured which form a first time ratio Δtᵥ₁.

Subsequently, a second integration pair is measured, with a first and a second integration procedure. The two integration procedures are referred to as 2a and 2b. The first integration procedure 2a corresponds to the integration procedure 1a. For the second integration procedure 2b, the following switch settings are made: S₁=“open”, S₄=“closed”, S₁₁=“closed” and S₁₃“U_{Ref}”. All other switches are “open”. The following therefore applies: U_{Z2}=U_{Ref} and U_{GL2}=U₄. The two measured time spans can in turn be set in relation to each other, and form the time ratio Δtᵥ₂.

Subsequently, a third integration pair is measured, with a first and a second integration procedure. The two integration procedures are referred to as 3a and 3b. These two integration procedures would correspond to the actual measurements for determining the voltage U₄ when the constants C_{21D} and C_{31D} are known. The integration procedure 3a corresponds in turn to the integration procedure 1a. For the integration procedure 3b, the following switch settings are made: S₁=“open”, S₄=“closed” and S₁₃=“earth”. All other switches are “open”. The following therefore applies: U_{Z2}=U₄ and U_{GL2}=U₄. From the measured time spans, a time ratio can in turn be formed which is referred to as Δtᵥ₃. If the values of U_{GL1}, U_{GL2}, U_{Z1} and U_{Z2} are formally inserted into the basic equation for each integration pair, together with the measured time ratio Δtᵥ an equation system results which consists of three equations with three unknowns. Based on the fact that U_{GL1}=0V, U_{GL2}=−U₄ and U_{Z1}=U_{Ref}, an equation system contains only the constants C_{21D} and C_{31D} as unknowns, together with the voltage U₄ of the battery cell Z₄ to be determined. The equation system can be clearly mathematically solved, and the unknowns, in particular U₄, can thus be determined.

During the next stage, the voltage U₅ of the battery cell Z₅ is determined using integration down. The constants C_{21D} and C_{31D} are already known. For determination purposes, a fourth integration pair is measured using a first and a second integration procedure. The integration procedures are referred to as 4a and 4b. The integration procedure 4a corresponds to the integration procedure 1a. For the second integration procedure 4b, the following switch settings are made: S₄=“closed” and S₅=“closed”. The following therefore applies: U_{Z2}=U₄+U₅ and U_{GL2}=−U₄. From the measured time spans of the integration procedures 4a and 4b, a time ratio Δtᵥ₄ can be formed. Through the formal insertion into the basic equation, an equation with the unknown U₅ is created. This equation can clearly be solved with the already determined and measured values. The voltage U₅ of the battery cell Z₅ is thus determined.

In the next stage, the constants C_{21U} and C_{31U} are determined for integration up. For this purpose, two reference integration pairs, each with a first and a second integration procedure, are measured. The first and second integration procedure of the first reference integration pair is referred to as 5a and 5b. For the first integration procedure 5a, the following switch settings are made: S₁=“open”, S₂=“open”, S₁₀=“closed”, S₁₂=“U_{Ref}” and S₁₃=“earth”. All other switches are “open”. The following therefore applies: U_{Z1}=−U_{Ref} and U_{GL1}=U_{Ref}. For the second integration procedure 5b, the following switch settings are made: S₂=“open”, S₅=“closed”, S₉=“closed” and S₁₂=“U_{Ref}”. All other switches are “open”. The following therefore results: U_{Z2}=−U_{Ref} and U_{GL2}=U₅+U_{Ref}. From the measured time spans from both integration procedures, a time ratio can in turn be formed, which is referred to as Δtᵥ₅. The second reference integration pair also comprises a first and a second integration procedure. The first and second integration procedure is referred to as 6a and 6b. The first integration procedure 6a corresponds to the integration procedure 5a. For the second integration procedure 6 b, the following switch settings are made: S₁=“open”, S₂=“open”, S₉=“closed”, S₁₂=“U_{Ref}” and S₁₃“earth”. All other switches are “open”. The following therefore results: U_{Z2}=−U_{Ref}−U₅ and U_{GL2}=U_{Ref}+U₅. From the two time spans measured, the time ratio Δtᵥ₆ can be formed. Through the formal insertion of the voltages and the measured time ratio into the basic equation, an equation system is created based on the two reference integration pairs which consists of two equations with two unknowns. The equation system of the second order contains as its sole unknown values the constants C_{21U} and C_{31U}. These can be clearly determined from the equation system.

In the following stage, the voltage U₃ of the battery cell Z₃ is determined using integration up. For this purpose, a first and a second integration procedure is conducted, which are referred to below as 7a and 7b. The integration procedure 7 a corresponds to the integration procedure 5a. For the integration procedure 7b, the following switch settings are made: S₃=“closed” and S₄=“open”. All other switches are “open”. Therefore, U_{Z2}=−U₃ and U_{GL2}=−U₄. The time ratio formed from the measured time spans is referred to as Δtᵥ₇. Through the formal insertion of the voltages and the time ratio into the basic equation, an equation results with U₃ as the unknown voltage. The voltage U₃ can thus be clearly determined.

During the next stage, the voltage U₂ is determined using integration down. For this purpose, a first and a second integration procedure is conducted, which are referred to below as 8a and 8b. The first integration procedure 8a corresponds to the integration procedure 1a. For the second integration procedure 8b, the following switch settings are made: S₂=“closed” and S₃=“closed”. All other switch settings are “open”. Therefore, U_{Z2}=U₂ and U_{GL2}=−U₂−U₃−U₄. From the two time spans measured, a time ratio can in turn be formed, which is referred to as Δtᵥ₈. Through the insertion of the voltages and the time ratio into the basic equation, the voltage U₂ can be clearly determined.

As a next stage, the voltage U₁ is determined using integration up. For this purpose, a first and a second integration procedure is in turn required, which are referred to below as 9a and 9b. The first integration procedure 9a corresponds to the integration procedure 5a. For the second integration procedure, the following switch settings are made: S₁=“closed” and S₂=“closed”. All other switches are “open”. Therefore U_{Z2}=−U₁ and U_{GL2}=−U₂−U₃−U₄. From the time spans measured, the time ration Δtᵥ₉ can be acquired. Through the insertion of the voltages and the time ratio into the basic equation, U₁ can clearly be calculated.

During the next stage, the voltage U₆ is determined using integration up. For this purpose, a first and a second integration procedure are in turn required, which are referred to below as 10a and 10b. The integration procedure 10a corresponds to the integration procedure 5a. For the second integration procedure 10b, the following switch settings are made: S₅“closed” and S₆=“closed”. All other switches are “open”. Therefore, U_{Z2}=−U₆ and U_{GL2}=U₅+U₆. From the measured time spans, the time ratio Δtᵥ₁₀ can be formed. Through the insertion of the voltages and the time ratio into the basic equation, U₆ can clearly be determined.

As a next stage, the voltage U₇ is determined using integration down. The first and second integration procedure required for this purpose are referred to below as 11a and 11b. The integration procedure 11a corresponds to the integration procedure 1a. For the second integration procedure 11b, the following switch settings are made: S₆=“closed” and S₇=“closed”. All other switches are “open”. Therefore, U_{Z2}=U₇ and U_{GL2}=U₅+U₆. From the measured time spans, the time ratio Δtᵥ₁₁ can be formed. Through the insertion of the voltages and the time ratio into the basic equation, the voltage U₇ can be clearly determined.

Finally, the voltage U₈ is determined using integration up. The integration procedures required for this purpose are referred to below as 12a and 12b. The first integration procedure 12a corresponds to the integration procedure 5a. For the second integration procedure, the following switch settings are made: S₇=“closed” and S₈=“closed”. All other switches are “open”. Therefore, U_{Z2}=−U₈ and U_{GL2}=U₅+U₆+U₇+U₈. From the measured time the time ratio Δtᵥ₁₂ can be formed. Through the insertion of the voltages and the time ratio into the basic equation, the voltage U₈ can clearly be calculated from already determined, known or measured values.

Thus all voltages U₁ to U₈ of the battery cells 14 are determined. The total measurement lasts maximum 50 ms. Due to the fact that the earth potential 17 has been selected to equal the potential of the node K₄, the maximum common mode voltage with the integration procedure 12b U_{GLmax}=U₅+U₆+U₇+U₈. The common mode voltage range of the integration circuit 2 can thus be limited to this maximum common mode voltage.

With less stringent precision standards, a differentiation between integration down and integration up is not required. In this case, the following applies: C_{21U}=C_{21D}=C₂₁ and C_{31U}=C_{31D}=C₃₁.

1-11. (canceled)

12. A measuring device (1) for determining a voltage of at least one battery cell (14) in a battery (15), the device comprising:
an integrator circuit (2) having a first circuit input (7) and a second circuit input (8) for applying a voltage, and a circuit output (9) for emitting an integrated value;
a reference voltage source (3) for specifying a reference voltage on the circuit inputs (7, 8) on the integrator circuit (2);
a first comparator circuit (4) having a first comparator input (1 0) which is connected with the circuit output (9) for comparing the integrated value with a first comparator threshold value, and a first comparator output (12) for emitting a first switching value when the first comparator threshold value is reached;
a second comparator circuit (5) with a second comparator input (11) which is connected with the circuit output (9) for comparing the integrated value with a second comparator threshold value, and a second comparator output (13) for emitting a second switching value when the second comparator threshold value is reached; and
a measuring unit (6) for measuring a time span between emission of a first switching value and emission of a second switching value, and for calculating the voltage of at least one of the battery cells (14) from the measured time span.

13. A device according to claim 12, wherein at least one of the integrator circuit (2), the first comparator circuit (4) and the second comparator circuit (5) is an analogue circuit.

14. A device according to claim 12, wherein the integrator circuit (2) comprises a capacitor (24) which is connected with an earth potential (1 7) of the measuring device (1).

15. A device according to claim 14, wherein the circuit output (9) of the integrator circuit (2) is the voltage which is released via the capacitor (24).

16. A device according to claim 14, wherein the earth potential (17) is identical with a potential of at least one battery cell (14).

17. A device according to claim 16, wherein the earth potential (17) is identical with a potential which is symmetrical to the battery cells (14).

18. A vehicle sensor according to claim 17, wherein in order to apply the voltages of several battery cells (14) which are connected in series to the integrator circuit (2), at least one battery cell switch (20) is provided for each battery cell (14).

19. A device according to claim 12, wherein the first comparator threshold value and the second comparator threshold value deviate from each other by at least 80% of the voltage to be determined.

20. A method for determining a voltage of at least one battery cell (14) of a battery (15) with a measuring device (1) comprising:
an integrator circuit (2) having a first circuit input (7) and a second circuit input (8) for applying a voltage, and a circuit output (9) for emitting an integrated value;
a reference voltage source (3) for specifying a reference voltage on the circuit inputs (7, 8) on the integrator circuit (2);
a first comparator circuit (4) having a first comparator input (10) which is connected with the circuit output (9) for comparing the integrated value with a first comparator threshold value, and a first comparator output (12) for emitting a first switching value when the first comparator threshold value is reached;
a second comparator circuit (5) with a second comparator input (11) which is connected with the circuit output (9) for comparing the integrated value with a second comparator threshold value, and a second comparator output (13) for emitting a second switching value when the second comparator threshold value is reached; and
a measuring unit (6) for measuring a time span between emission of a first switching value and emission of a second switching value, and for calculating the voltage of at least one of the battery cells (14) from the measured time span;
the method comprising:
preparing the measuring device (1) which is connected to the battery (15);
applying a voltage comprising the reference voltage to the circuit inputs (7, 8) of the integrator circuit (2);
completing a first integration procedure until the circuit output (9) reaches the first and the second comparator threshold value;
measuring a first time span between the emission of the first and the second switching value;
applying a voltage comprising the voltage of a battery cell (14) to be determined to the circuit inputs (7, 8) of the integrator circuit (2);
completing a second integration procedure until the circuit output (9) reaches the first and the second comparator threshold value;
measuring a second time span between the emission of the first and the second switching values; and
determining the voltage of the battery cell (14) using the measured first and second time span and the reference voltage.

21. A method according to claim 20, wherein the first and second integration procedures comprise an identical integration direction.

22. A method according to claim 21, wherein the end of the first integration procedure and the beginning of the second integration procedure comprise a time difference of maximum 2 ms.
